(19) United States
(12) Patent Application Publication
(10) Pub. No.: US 2008/0207016 A1
(43) Pub. Date: Aug. 28, 2008

(54) COMMUNICATIONS MODULE

(76) Inventors: Kuan-Hsing Li, Taichung City (TW); Kuo-Hsien Liao, Taichung City (TW); Chia-Yang Chen, Taichung City (TW)

Correspondence Address: OSTROLENK FABER GERB & SOFFEN, 1180 AVENUE OF THE AMERICAS, NEW YORK, NY, 100368403, US

(21) Appl. No.: 11/680,202

(22) Filed: Feb. 28, 2007

(51) Int. Cl. H05K 1/18

(52) U.S. Cl. 439/76.1

(57) ABSTRACT

A communications module includes: a circuit board having a peripheral end; a first electronic component mounted on the circuit board; a plurality of second electronic components mounted on the circuit board and having a structural strength less than that of the first electronic component; and a metal cover secured to the peripheral end of the circuit board. The metal cover includes a top wall disposed over the first and second electronic components and formed with a protrusion protruding toward the first electronic component. The distance between the protrusion and the first electronic component is less than the distance between the top wall of the cover and the second electronic components.

### BACKGROUND OF THE INVENTION

1. Field of the Invention

The invention relates to a communications module, more particularly to a communications module including a circuit board with an electronic component and a metal cover formed with a protrusion protruding toward the electronic component.

2. Description of the Related Art

Referring to FIGS. 1 and 2, a conventional communications module 10 includes a circuit board 11, a plurality of electronic components 12 mounted on the circuit board 11, and a metal cover 13 secured to a peripheral end of the circuit board 11 and enclosing the electronic components 12.

The metal cover 13 includes a top wall 131 disposed over and spaced apart from the electronic components 12, and a surrounding wall 132 extending transversely and downwardly from the top wall 131 and soldered to the circuit board 11 through a plurality of soldering pads 14.

Due to a large soldering area between the metal cover 13 and the circuit board 11, miniaturization of the communications module 10 is hindered.

FIGS. 3, 4 and 5 illustrate another conventional communications module 20 that can achieve the miniaturization purpose. The communications module 20 includes a circuit board 21, a plurality of electronic components 22, and a metal cover 23. The metal cover 23 includes a top wall 231 disposed over the electronic components 22 and a plurality of leg portions 232 extending transversely and downwardly from the top wall 231 and soldered to the circuit board 21 through a plurality of soldering pads 24.

However, the overall structural strength of the metal cover 23 becomes poor due to the reduction in the dimension of the surrounding part of the metal cover 2, and the top wall 231 tends to flex downwardly when an external force is applied thereto. As such, when the top wall 231 is flexed downwardly to an extent to press against one of the electronic components 22, as best illustrated in FIG. 5, the pressed one of the electronic components 22 is likely to be damaged as a result of the pressing action.

### SUMMARY OF THE INVENTION

Therefore, the object of the present invention is to provide a communications module that can overcome the aforesaid drawbacks associated with the prior art.

Accordingly, there is provided a communications module that comprises: a circuit board having a peripheral end; a first electronic component mounted on the circuit board; a plurality of second electronic components mounted on the circuit board and having a structural strength less than that of the first electronic component; and a metal cover including a top wall and a plurality of leg portions extending between the top wall and the circuit board and secured to the peripheral end of the circuit board. The top wall is disposed over and is spaced apart from the first and second electronic components and is formed with a protrusion protruding downwardly toward and spaced apart from the first electronic component. The distance between the protrusion and the first electronic component is less than the distance between the top wall of the metal cover and the second electronic components so that when the top wall is flexed downwardly, the protrusion is brought to abut against the first electronic component, thereby preventing further downward flexing of the top wall.

### BRIEF DESCRIPTION OF THE DRAWINGS

Other features and advantages of the present invention will become apparent in the following detailed description of the preferred embodiments with reference to the accompanying drawings, of which:

FIG. 1 is an assembled perspective view of a conventional communications module;

FIG. 2 is a schematic top view of the conventional communication module of FIG. 1;

FIG. 3 is an assembled perspective view of another conventional communications module;

FIG. 4 is a schematic top view of the conventional communications module of FIG. 3;

FIG. 5 is a partly sectional view of the conventional communications module of FIG. 4;

FIG. 6 is an assembled perspective view of the first preferred embodiment of a communications module according to the present invention;

FIG. 7 is a schematic top view of the first preferred embodiment;

FIG. 8 is a partly sectional view taken along line VIII-VIII in FIG. 7, illustrating a configuration of a top wall of a metal cover at an initial state;

FIG. 9 is a view similar to FIG. 8, but illustrating the configuration of the top wall of the metal cover at a flexed state; and

FIG. 10 is an assembled perspective view of the second preferred embodiment of the communications module according to the present invention.

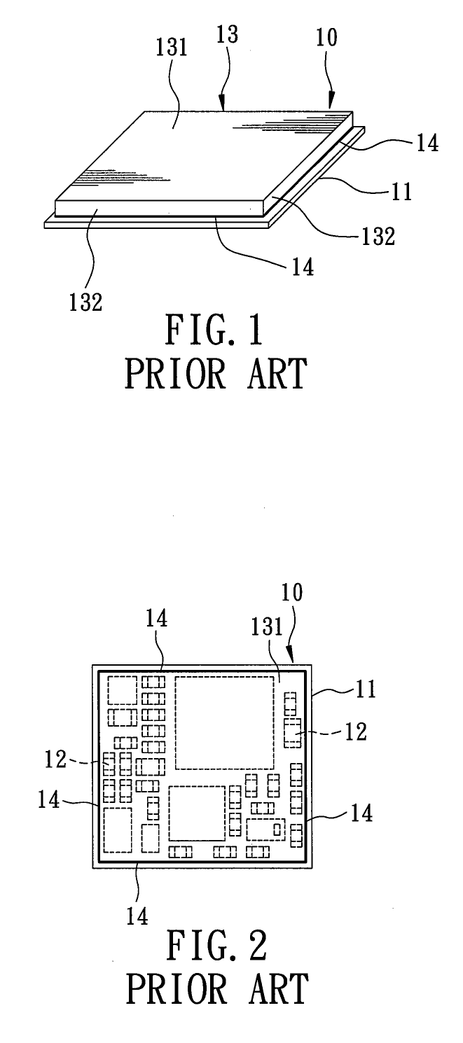

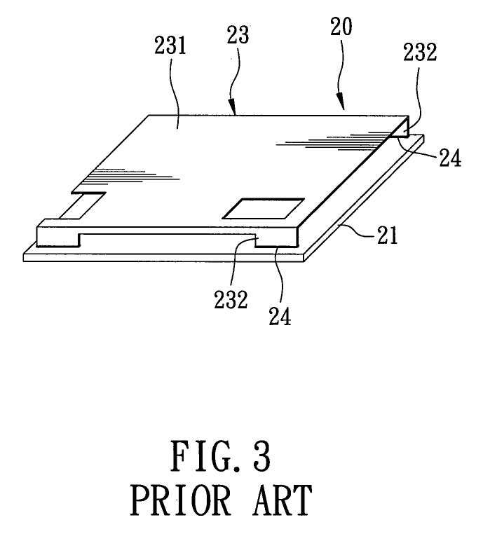

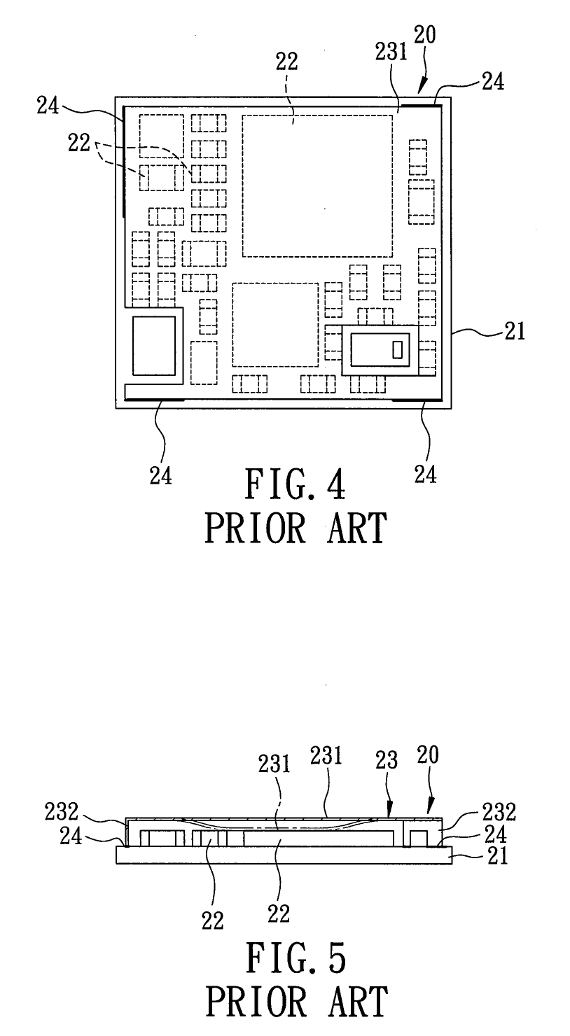

### DETAILED DESCRIPTION OF THE PREFERRED EMBODIMENTS

Before the present invention is described in greater detail with reference to the accompanying preferred embodiments, it should be noted herein that like elements are denoted by the same reference numerals throughout the disclosure.

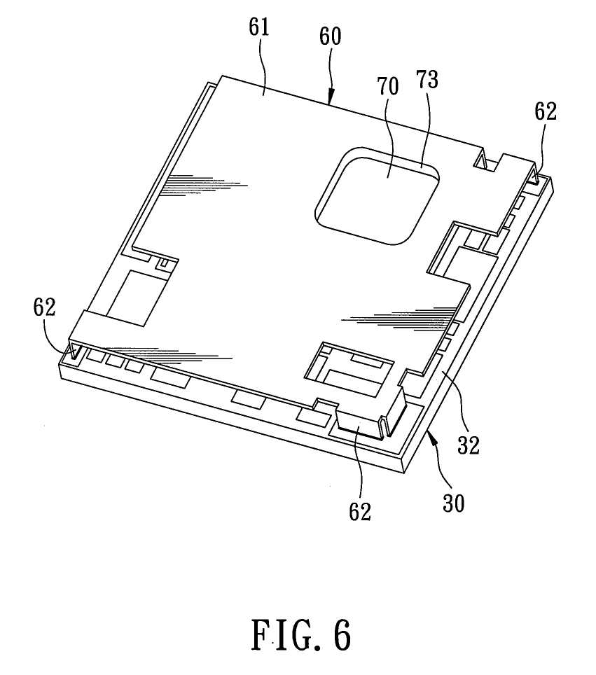

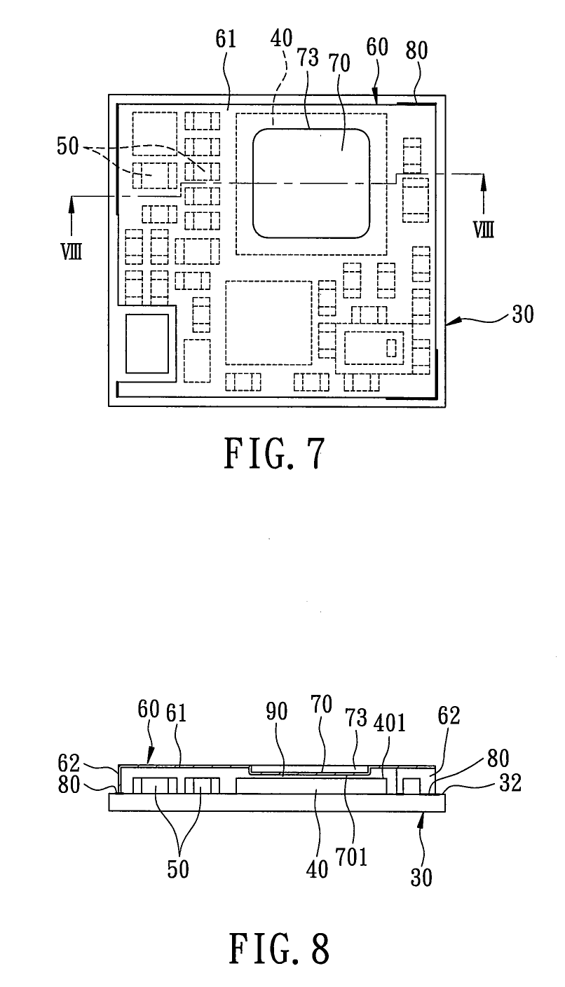

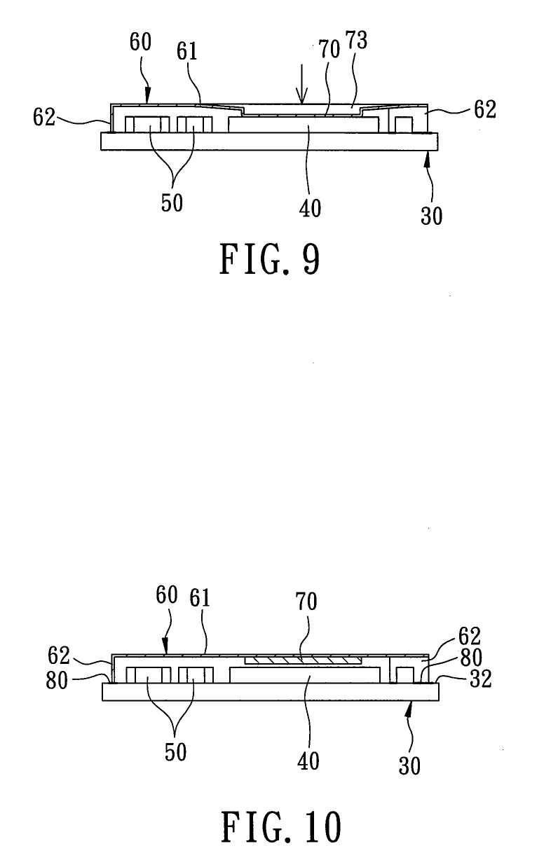

Referring to FIGS. 6, 7 and 8, the first preferred embodiment of a communications module according to the present invention is shown to include: a circuit board 30 having a peripheral end; a first electronic component 40 mounted on the circuit board 30; a plurality of second electronic components 50 mounted on the circuit board 30 and having a structural strength less than that of the first electronic component 40; and a metal cover 60 secured to the peripheral end of the circuit board 30 and covering the first and second electronic components 40, 50. The metal cover 60 includes a top wall 61 disposed over and spaced apart from the first and second electronic components 40, 50 and formed with a protrusion 70 protruding downwardly toward and spaced apart from the first electronic component 40. The distance between the protrusion 70 and the first electronic component 40 is less than the distance between the top wall 61 of the metal cover 60 and the second electronic components 50 so that when the top wall 61 is flexed downwardly, the protrusion 70 is brought to abut against the first electronic component 40, thereby preventing further downward flexing of the top wall 61, as best shown in FIG. 9.

In this embodiment, the top wall 61 of the metal cover 60 has an indentation that is indented toward the first electronic component 40 to define the protrusion 70. The protrusion 70 has a bottom face 701, and the first electronic component 40 has a top face 401 with a size larger than that of the bottom face 701 of the protrusion 70.

The metal cover 60 further has a plurality of leg portions 62 bent and extending transversely and downwardly from the top wall 61 and secured to the peripheral end of the circuit board 30 through soldering pads 80 in a conventional manner.

In this embodiment, the first electronic component 40 is a surface mount device mounted fixedly on a top side 32 of the circuit board 30. Preferably, the first electronic component 40 is a quad flat no lead package (QFN) component, a thin-shrink small outline package (TSSOP) component, or a flip-chip package component, etc.

The second electronic components 50 are surface mount devices mounted fixedly on the top side 32 of the circuit board 30, and normally include a ceramic filter, a ceramic capacitor, and a ceramic inductor.

In this embodiment, the protrusion 70 together with the indentation 73 is formed through punching techniques. The protrusion 70 cooperates with the first electronic component 40 to form a clearance 90 therebetween at an initial state of the metal cover 60.

In use, as shown in FIGS. 8 and 9, when the top wall 61 is flexed downwardly by an external force (ex., a test force), the protrusion 70 is brought to abut against the first electronic component 40, thereby preventing further downward flexing of the top wall 61 and damage to the second electronic components 50. Hence, with the inclusion of the protrusion 70 in the communications module of this invention, the aforesaid drawbacks associated with the prior art can be eliminated.

Referring to FIG. 10, the second preferred embodiment of this invention differs from the previous embodiment in that the protrusion 70 of the second preferred embodiment is not formed by punching the metal cover 60, and is instead a separate piece in the form of a rigid body which is attached securely to an inner side of the top wall 61 of the metal cover 60.

While the present invention has been described in connection with what are considered the most practical and preferred embodiments, it is understood that this invention is not limited to the disclosed embodiments but is intended to cover various arrangements included within the spirit and scope of the broadest interpretation so as to encompass all such modifications and equivalent arrangements.

1. A communications module comprising:
a circuit board having a peripheral end;
a first electronic component mounted on said circuit board;
a plurality of second electronic components mounted on said circuit board and having a structural strength less than that of said first electronic component; and
a metal cover having a top wall disposed over said first and second electronic components, said top wall having with a protrusion protruding downwardly toward said first electronic component, said protrusion being spaced apart from said electronic component and said second electronic components, the distance between said protrusion and said first electronic component is being less than the distance between said top wall of said metal cover and said second electronic components, said metal cover further having a plurality of leg portions extending between said top wall and said circuit board, said leg portions being secured to said peripheral end of said circuit board.

2. The communications module as claimed in claim 1, wherein said top wall of said metal cover has an indentation that is indented toward said first electronic component to define said protrusion.

3. The communications module as claimed in claim 1, wherein said protrusion has a bottom face, said first electronic component having a top face with a size larger than that of said bottom face of said protrusion.

4. The communications module as claimed in claim 1, wherein said top wall of said metal cover has an inner side, said protrusion being in the form of a rigid body that is attached securely to said inner side of said top wall.

5. The communications module as claimed in claim 1, wherein said first electronic component is a surface mount device.

6. The communications module as claimed in claim 1, wherein said second electronic components are surface mount devices that include a ceramic filter, a ceramic capacitor, and a ceramic inductor.
